(19) United States
(12) Patent Application Publication
(10) Pub. No.: US 2023/0120305 A1
(43) Pub. Date: Apr. 20, 2023

(54) TESTING A SEMICONDUCTOR DIE USING TEMPORARY TEST PADS APPLIED TO CONDUCTIVE PADS OF THE SEMICONDUCTOR DIE

(71) Applicant: ADVANCED MICRO DEVICES, INC., Santa Clara, CA (US)

(72) Inventors: CHIA-HAO CHENG, HSINCHU CITY (TW); RAHUL AGARWAL, LIVERMORE, CA (US); CHINTAN BUCH, SANTA CLARA, CA (US); ARSALAN ALAM, AUSTIN, TX (US)

(21) Appl. No.: 17/965,888

(22) Filed: Oct. 14, 2022

Related U.S. Application Data
(60) Provisional application No. 63/255,772, filed on Oct. 14, 2021.

(51) Int. Cl. H01L 21/66; H01L 23/48; H01L 23/00; H01L 21/463; H01L 21/465; H01L 21/3205

(52) U.S. Cl. CPC H01L 22/32; H01L 22/14; H01L 23/481; H01L 24/11; H01L 24/16; H01L 21/463; H01L 21/465; H01L 21/32051; H01L 2224/16014

(57) ABSTRACT

A method includes applying a temporary pad to a conductive pad of a semiconductor die. After testing the semiconductor die, the temporary pad is removed from the conductive pad.

### BACKGROUND

Known good die (KGD) testing of semiconductor dies determines whether a semiconductor die is reliable before a semiconductor die is included in a semiconductor assembly. Many methods for KGD testing involve use of a probe card that includes various probes that contact pads of a semiconductor die to perform one or more tests evaluating reliability of the semiconductor die. Contact between a probe of a probe card and a semiconductor die pad results in a mark or indentation in the pad. Such marks or indentations render the pad unsuitable for subsequent use with a solder bump.

### BRIEF DESCRIPTION OF THE DRAWINGS

FIG. 1 is a cross-section of a conventional semiconductor die after testing the semiconductor die according to some implementations.

FIG. 2 is a cross section of a semiconductor die having a temporary pad prior to testing the semiconductor die according to some implementations.

FIG. 3 is a cross section of the semiconductor die that included a temporary pad after the semiconductor die was tested according to some implementations.

FIG. 4 is a cross-section of a semiconductor die that included a temporary pad configured to be coupled to other devices after testing according to some implementations.

FIG. 5 is a cross-section of another semiconductor die that included a temporary pad configured to be coupled to other devices after testing according to some implementations.

FIG. 6 is an example integrated circuit device including a semiconductor die tested using a temporary pad according to some implementations.

FIG. 7 is an example computing device according to some implementations.

FIG. 8 is a flowchart of a method for testing a semiconductor die according to some implementations.

### DETAILED DESCRIPTION

KGD testing of semiconductor dies determines whether a semiconductor die is reliable before a semiconductor die is included in a semiconductor assembly. For example, KGD testing applies logic patterns to a die to induce thermal stress in the die, allowing evaluation of the die for temperature-related defects. Methods for performing KGD testing have probes of a probe card in physical contact with pads of a semiconductor die to perform one or more tests evaluating reliability of the semiconductor die. Such contact prevents the pad from subsequently being used with a solder bump or other type of connector. Marks left on a pad from contact with a probe create potential reliability issues with a solder bump or other type of connector applied to the pad. For example, contact by the probe of the probe card leaves cracks or voids on the pad that induce high resistance in a solder bump subsequently applied to the pad.

Conventional methods for performing KGD testing reduce an available area of a die available for components. For example, increasing a pad size to allow a probe to contact a portion of the pad without contacting another portion of the pad allows the portion of the pad that did not contact the probe to be used for a solder bump. However, increasing the pad size increases crosstalk between conductive traces in the die and reduces an amount of space on the die for routing or other electrical features. Another example for performing KGD testing uses contactless testing where a die includes an antenna, and the tests are wirelessly received by the die via the antenna. However, wireless testing involves including an antenna in each die, while wireless transmission limits an amount of power that can be used for testing.

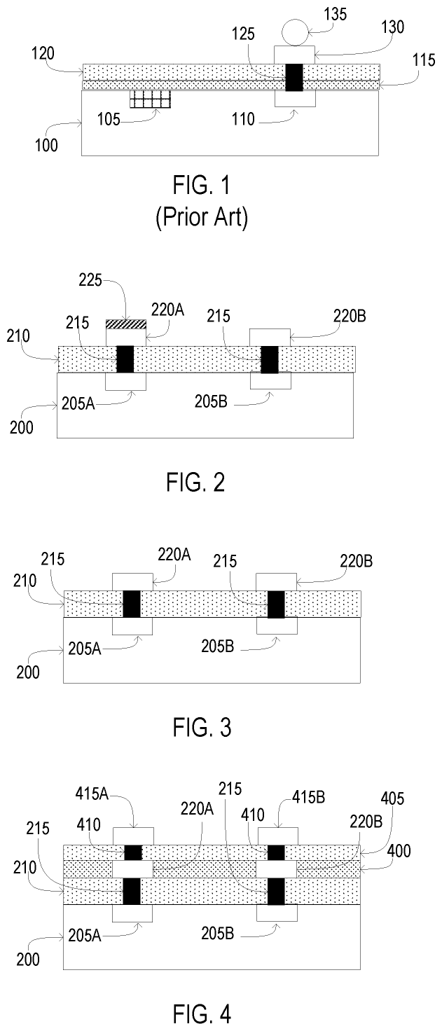

Other conventional methods for performing KGD testing include use of a sacrificial pad in a die. The sacrificial pad is used as a contact point for a probe, but the sacrificial pad is not subsequently used for a solder bump or other connection. FIG. 1 shows a cross-section of a conventional die 100 including a sacrificial pad 105 that was used for testing the die 100. In the example of FIG. 1, the die 100 includes the sacrificial pad 105 and an active pad 110. The sacrificial pad 105 and the active pad 110 each comprise a conductive material, such as aluminum.

To perform KGD testing of the die 100, a probe contacts the sacrificial pad 105 to provide signals, such as logic patterns, to the die 100. After testing, the probe is removed from the sacrificial pad 105, and a bonding layer 115 covers the sacrificial pad 105 and the active pad 110. A passivation layer 120 is applied over the bonding layer 115. The passivation layer 120 isolates devices in the die 100 from environmental contaminants. For example, the passivation layer 120 is a polyimide in various implementations.

As shown in FIG. 1, a via 125 is formed through the bonding layer 115 and the passivation layer 120, with an end of the via 125 coupled to the active pad 110 of the die 100. An opposite end of the via 125 is coupled to a conductive pad 130 that is on top of the passivation layer 120. A solder bump 135 is coupled to the conductive pad 130, allowing another device to be coupled to the active pad 110 using the solder bump 135, the conductive pad 130, and the via 125. In other implementations, connectors other than a solder bump 135 are used to couple another device to the conductive pad 130. However, as shown in FIG. 1, the sacrificial pad 105 remains covered by the passivation layer 120 and the bonding layer 115, preventing other devices from being coupled to the sacrificial pad 105. Hence, in conventional configurations, the sacrificial pad 105 is used for KGD testing of the die 100, but is covered and unused for subsequent connections to the die 100. Leaving the sacrificial pad 105 covered by the passivation layer 120 and the bonding layer 120 reduces an area of the die 100 capable of being used after testing, reducing the area of the die 100 that is useable for connection with other devices.

To enable KGD testing of a die without sacrificing an area of the die available for subsequent connections, the present specification describes applying a temporary pad to a conductive pad of the die. A probe contacts the temporary pad and communicates signals, such as logic patterns, to the die for performing one or more tests. After testing, the temporary pad is removed, revealing the conductive pad. As the probe contacted the temporary pad, the conductive pad is not damaged from application of the probe. This allows a solder bump to subsequently be applied to the conductive pad. Hence, the present specification allows KGD testing to be performed without reducing a number of conductive pads capable of being used for connections to the die after testing. Additionally, applying the temporary pad to the conductive pad allows a useable life of a probe to be extended by applying a temporary pad that is a material softer than the probe to the conductive pad. In such implementations, the temporary pad protects both the conductive pad from damage by the probe and protects the probe from damage by contacting the conductive pad.

To that end, the present specification sets forth various implementations of a method including applying a temporary pad to a conductive pad of a semiconductor die and, after testing the semiconductor die, removing the temporary pad. In some implementations, testing the semiconductor die includes coupling a probe to the temporary pad and executing one or more tests of the semiconductor die using the probe. After executing the one or more tests, the temporary pad is removed from the conductive pad in some implementations. In some implementations, applying the temporary pad to the conductive pad includes applying a layer of metal to a top surface of the conductive pad. In various implementations, applying the temporary pad to the conductive pad includes electroplating the layer of metal to the top surface of the conductive pad. In some implementations, applying the temporary pad to the conductive pad includes applying a layer of solder to a top surface of the conductive pad.

In some implementations, removing the temporary pad includes griding away the temporary pad to expose the conductive pad. In various implementations, removing the temporary pad includes chemical-mechanical polishing away the temporary pad to expose the conductive pad.

In some implementations, the conductive pad is coupled to an active pad of the semiconductor die by a via passing through a passivation layer covering the active pad. In some embodiments, the method further includes applying a bonding layer to a top surface of the passivation layer after removing the temporary pad, where the bonding film covering the conductive pad. The method applies a second passivation layer to a top surface of the bonding film and forms a second via in the second passivation layer, where the second via traverses through the second passivation layer and has an end coupled to the conductive pad and an opposite end coupled to an external conductive pad in various implementations. The method further applies a solder bump to the external conductive pad in some implementations. In some implementations, the method includes removing one or more portions of the conductive pad to leave a remaining portion of the conductive pad, applying a second passivation layer to a top surface of the conductive pad, and forming a second via in the second passivation layer, where the second via traversing through the second passivation layer and has an end coupled to the remaining portion of the conductive pad and an opposite end coupled to an external conductive pad.

The present specification also describes a semiconductor die including an active pad covered by a passivation layer. A via traverses through the passivation layer, with an end of the via coupled to the active pad and an opposite end of the via coupled to a conductive pad. A temporary pad is applied to the conductive pad. In some implementations, the temporary pad is applied to a top surface of the conductive pad. In some implementations, the temporary pad is a layer of metal. The layer of metal is electroplated to the temporary pad in some implementations. In various implementations, the temporary pad is a layer of solder

The present specification further describes a semiconductor die including an active pad and a passivation layer covering the active pad. A via traverses through the passivation layer, with an end of the via coupled to the active pad. The semiconductor die further includes a second passivation layer applied to a surface of the passivation layer nearest an opposite end of the via from the end of the via. A second via traverses through the second passivation layer and has a first end coupled to the opposite end of the via and a second end coupled to an external conductive pad. In some implementations, the opposite end of the via is coupled to a conductive pad positioned on top of the passivation layer and the second end of the second via is coupled to the conductive pad. In some implementations, a solder bump is coupled to the external conductive pad.

The following disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows include implementations in which the first and second features are formed in direct contact, and also include implementations in which additional features formed between the first and second features, such that the first and second features are in direct contact. Further, spatially relative terms, such as “beneath,” “below,” “lower,” “above,” “upper,” “back,” “front,” “top,” “bottom,” and the like, are used herein for ease of description to describe one element or feature's relationship to another element(s) or feature(s) as illustrated in the figures. Similarly, terms such as “front surface” and “back surface” or “top surface” and “back surface” are used herein to more easily identify various components, and identify that those components are, for example, on opposing sides of another component. The spatially relative terms are intended to encompass different orientations of the device in use or operation in addition to the orientation depicted in the figures.

FIG. 2 is a cross section of a semiconductor die 200 having a temporary pad 225 prior to testing the semiconductor die 200. The semiconductor die 200 includes one or more active pads 205A, 205B. Each pad 205A, 205B comprises conductive material. For example, a pad 205A, 205B is copper or aluminum.

A passivation layer 210 covers the pads 205A, 205B. In some implementations, the passivation layer 210 is silicon dioxide or silicon nitride. The passivation layer 210 comprises different materials in different embodiments. The passivation layer 120 seals the pads 205A, 205B to prevent or to slow deterioration of electronic properties of the die 200 from environmental conditions. Further, the passivation layer 210 provides a protective barrier from environmental contaminants or moisture for the pads and for devices within the die 200.

A via 215 is formed through the passivation layer 210 for each pad 205A, 205B. The via 215 includes conductive material (e.g., aluminum, copper). An end of a via 215 is coupled to a pad 205A, 205B. Hence, a via 215 passes through the passivation layer 210 and is conductively coupled to a pad 205A, 205B of the die 200. An opposite end of the via 215 is coupled to a conductive pad 220A, 220B. Each conductive pad 220A, 220B comprises a conductive material, such as aluminum or copper. The conductive pad 220A, 220B is on top of the passivation layer 210. Thus, a via 215 conductively couples a pad 205A, 205B to a corresponding conductive pad 220A, 220B on top of the passivation layer 210. In the example of FIG. 2, pad 205A is coupled to conductive pad 220A using a via 215, while another via 215 couples pad 205B to conductive pad 220B.

To enable testing, such as KGD testing, of the die 200 without damaging a conductive pad 220A, 220B, a temporary pad 225 is applied to at least one conductive pad 220A, 220B. In the example of FIG. 2, the temporary pad 225 is applied to conductive pad 220A, while no temporary pad is applied to conductive pad 220B. However, in other implementations, a temporary pad 225 is applied to multiple conductive pads 220A, 220B. The temporary pad 225 is a layer of solder in some implementations. In other implementations, the temporary pad 225 is a layer of metal, such as copper or aluminum. Where the temporary pad 225 is a layer of metal, the temporary pad 225 is applied to a conductive pad 220A, 220B using electroplating in some implementations. In other implementations, different conductive materials are used for the temporary pad 225.

In various implementations, a conductive material selected for the temporary pad 225 is selected based on a probe to be coupled to the temporary pad 225 to test the die 200. The conductive material used for the temporary pad 225 is softer than a portion of the probe that contacts the temporary pad 225 in various implementations. Such a selection of the conductive material for the temporary pad 225 prevents the temporary pad 225 from damaging the probe when the probe is coupled to, or contacts, the temporary pad 225. This allows the temporary pad 225 to both protect the conductive pad 220A, 220B from being scratched or otherwise damaged by the probe and protect the probe from being damaged from contacting the temporary pad 225.

FIG. 3 shows a cross section of the semiconductor die 200 after the semiconductor die 200 has been tested. To test the semiconductor die 200, a probe is coupled to the temporary pad 225. The probe provides signals to the semiconductor die 220A, 220B through the temporary pad 225 and the conductive pad 220A, 220B to which the probe was coupled. For example, the probe is coupled to temporary pad 225 of the semiconductor die 200 and transmits signals to one or more devices comprising the semiconductor die 200 via conductive pad 220A and via 215 to test the semiconductor die 200.

After testing the semiconductor die 200, the probe is decoupled from the temporary pad 225, and the temporary pad 225 is removed from the conductive pad 220A. For example, after transmitting a set of logic patterns to the semiconductor die 200 via the temporary pad 225 and the conductive pad 220A, the probe is decoupled from the temporary pad 225. In some implementations, the temporary pad 225 is removed by grinding the temporary pad 225 away from the conductive pad 220A. In other embodiments, chemical mechanical polishing is used to remove the temporary pad 225 from the conductive pad 220A. Removing the temporary pad 225 exposes the conductive pad 220A. As the probe was coupled to the temporary pad 225, the probe does not mark or damage the conductive pad 220A, allowing the conductive pad 220A to be subsequently used for coupling one or more devices to the semiconductor die 200.

For further illustration, FIG. 4 shows a semiconductor die 200 that included a temporary pad 225 configured to be coupled to other devices after testing. As further described above in conjunction with FIG. 2, the semiconductor die 200 includes active pads 205A, 205B and vias 215 coupling the active pads 205A, 205B to a corresponding conductive pad 220A, 220B. The vias 215 travel through a passivation layer 210 to couple the active pads 205A, 205B to the corresponding conductive pads 220A, 220B that are on top of the passivation layer 210.

After removing the temporary pad 225 from the conductive pad 220A, a bonding layer 400 is applied to a top surface of the passivation layer 210. The bonding layer 400 covers the conductive pads 220A, 220B. A second passivation layer 405 is applied to the bonding layer 400, with the second passivation layer 405 protecting the conductive pads 220A, 220B and devices within the semiconductor die 200 from environmental conditions, such as contaminants or moisture. In various implementations, the second passivation layer 405 comprises silicon dioxide or silicon nitride, while other materials are used in other implementations. Hence, the second passivation layer 405 provides a protective barrier from the external environment for the conductive pads 220A, 220B and for devices included in the semiconductor die 200.

A second via 410 through the second passivation layer 405 and the bonding layer 400 is formed for each conductive pad 220A, 220B. A second via 410 has an end coupled to a conductive pad and an opposite end coupled to an external conductive pad 415A, 415B. The second via 410 includes a conductive material, so the second via 410 conductively couples an external conductive pad 415A, 415B to a corresponding conductive pad 220A, 220B. In the example of FIG. 4, the conductive pad 220A is conductively coupled to the external conductive pad 415A by a via, while another via conductively couples the conductive pad 220B to the external conductive pad 415B. Each external conductive pad 415A, 415B comprises a conductive material. For example, an external conductive pad 415A, 415B is copper, aluminum, or another conductive metal.

As shown in FIG. 4, the conductive pad 220A used when testing the semiconductor die 200 is capable of being coupled to another device through the external conductive pad 415A and the second via 415A, 415B. In contrast, as shown in FIG. 1, a sacrificial pad 105 used for testing a conventional semiconductor die 100 is unable to be coupled to another device after testing. The conventional semiconductor die 100 shown in FIG. 1 covers the sacrificial pad 105 after testing is completed, resulting in a pad of the conventional semiconductor die 100 being unusable for coupling to another device. In contrast, the semiconductor die 200 of FIG. 4 has the conductive pad 220A used during testing of the semiconductor die 200 available for coupling to another device. Hence, applying the temporary pad 225 to the conductive pad 220A for testing the semiconductor die 200 allows subsequent use of the conductive pad 220A for coupling to another device, increasing a number of pads 220A, 220B of the semiconductor die 200 that can be coupled to other devices after the semiconductor die 200 has been tested.

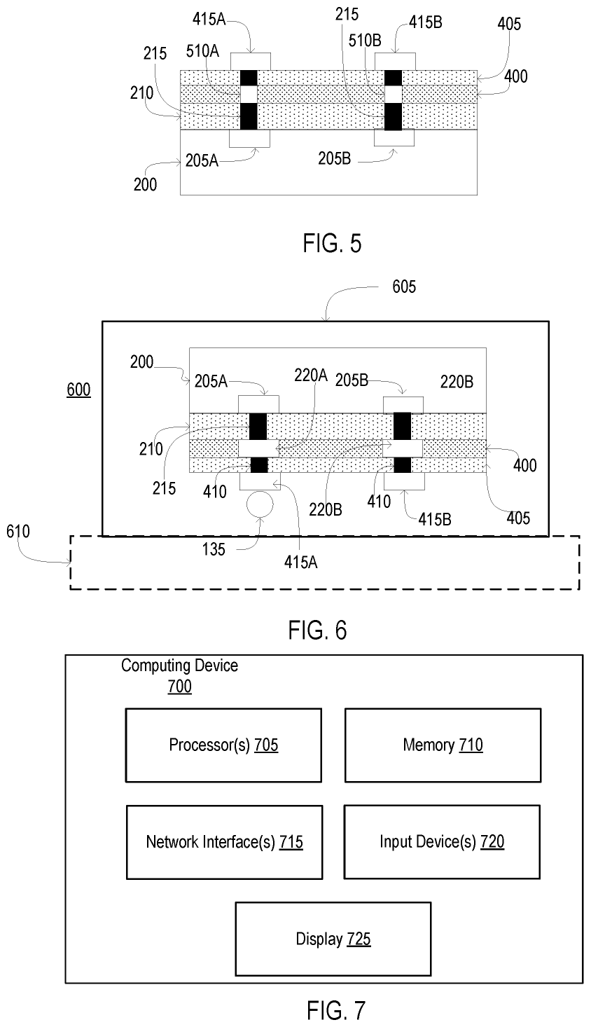

FIG. 5 shows another semiconductor die 200 that included a temporary pad 225 configured to be coupled to other devices after testing. The semiconductor die 200 shown in FIG. 5 includes active pads 205A, 205B and vias 215 coupling the active pads 205A, 205B to a corresponding conductive pad 220A, 220B. The vias 215 travel through a passivation layer 210 to couple the active pads 205A, 205B to the corresponding conductive pads 220A, 220B that are on top of the passivation layer 210, as further described above in conjunction with FIGS. 4 and 5.

After removing the temporary pad 225 from the conductive pad 220A, one or more portions of at least one conductive pad 220A, 220B are removed. For example, removing the one or more portions from the conductive pad 220A leaves a remaining portion 510A of the conductive pad 220A. The remaining portion 510A of the conductive pad 220A has a smaller area than the conductive pad 220A. Similarly, FIG. 5 shows a remaining portion 510B of the conductive pad 220B after one or more portions of the conductive pad 220B have been removed. In some implementations, the portions of a conductive pad 220A, 220B are removed through grinding. In other implementations, the portions of the conductive pad 220A, 220B are removed through chemical mechanical polishing. However, in other implementations, other methods are used to remove the one or more portions of a conductive pad. Further, in some implementations, the portions of a conductive pad 220A, 220B that are removed are based on a width of the via 215 coupling a pad 205A, 205B to a corresponding conductive pad 220A, 220B. For example, portions of a conductive pad 220A, 220B are removed so a width of the remaining portions 510A, 510B of the conductive pad 220A, 220B is within a threshold amount of a width of the via 215 coupled to the conductive pad 220A, 220B, or so the width of the remaining portions 510A. 510B of the conductive pad 220A, 220B is within a threshold amount of the width of the via 215 coupled to the conductive pad 220A, 220B.

In FIG. 5, a bonding layer 400 is applied to a top surface of the passivation layer 210 after removing portions from conductive pads 220A, 220B. The bonding layer 400 covers the remaining portions 510A. 510B of the conductive pads 220A, 220B. A second passivation layer 405 is applied to the bonding layer 400, with the second passivation layer 405 protecting the remaining portions of the conductive pads 205A, 205B and devices within the semiconductor die 200 from environmental conditions, as further described above in conjunction with FIGS. 2 and 4.

A second via 410 through the second passivation layer 405 and the bonding layer 400 is formed for each remaining portion 510A, 510B of a conductive pad 220A, 220B. A second via 410 has an end coupled to a conductive pad and an opposite end coupled to an external conductive pad 415A, 415B. The second via 410 includes a conductive material, so the second via 410 conductively couples an external conductive pad 415A, 415B to a corresponding conductive pad 220A, 220B. In the example of FIG. 5, the remaining portion 510A of the conductive pad 220A is conductively coupled to the external conductive pad 415A by a via 410, while another via 410 conductively couples the remaining portion 510B of the conductive pad 220B to the external conductive pad 415B. Each external conductive pad 415A, 415B comprises a conductive material. For example, an external conductive pad 415A, 415B can be copper, aluminum, or another conductive metal. In this way, the semiconductor die 200 shown in FIG. 5 allows subsequent use of the conductive pad 220A for coupling to another device, increasing a number of pads 220A, 220B of the semiconductor die 200 that can be coupled to other devices after the semiconductor die 200 has been tested, while reducing dimensions of the conductive pads 220A, 220B that were used when testing the semiconductor die 200.

FIG. 6 is a cross-sectional diagram of an example integrated circuit device 600 including a semiconductor die 200 tested using a temporary pad. The example integrated circuit device 600 can be implemented in a variety of computing devices, including mobile devices, personal computers, peripheral hardware components, gaming devices, set-top boxes, smart phones, and the like (as shown in FIG. 7). The example integrated circuit device 600 of FIG. 6 includes a component 605. The component 605 includes a die 200, which is a block of semiconducting material such as silicon onto which a functional integrated circuit is fabricated. As an example, the die 200 includes a processor such as a Central Processing Unit (CPU), a Graphics Processing Unit (GPU), or other processor as can be appreciated. In various implementations, the die 200 was tested using a temporary pad 225 applied to a conductive pad 220A, 220B of the die, with the temporary pad 225 removed from the conductive pad 220A, 220B after testing was completed, as further described above in conjunction with FIGS. 2-5.

As an example, the die 200 includes a processor 705 of a computing device 700 as shown in FIG. 7. The computing device 700 is implemented, for example, as a desktop computer, a laptop computer, a server, a game console, a smart phone, a tablet, and the like. In addition to one or more processors 705, the computing device 700 includes memory 710. The memory 710 includes Random Access Memory (RAM) or other volatile memory. The memory 710 also includes non-volatile memory such as disk storage, solid state storage, and the like.

In some implementations, the computing device 700 also includes one or more network interfaces 715. In some implementations, the network interfaces 715 include a wired network interface 715 such as Ethernet or another wired network connection as can be appreciated. In some implementations, the network interfaces 715 include wireless network interfaces 715 such as Wi-Fi, BLUETOOTH®, cellular, or other wireless network interfaces 715 as can be appreciated. In some implementations, the computing device 700 includes one or more input devices 720 that accept user input. Example input devices 720 include keyboards, touchpads, touch screen interfaces, and the like. One skilled in the art will appreciate that, in some implementations, the input devices 720 include peripheral devices such as external keyboards, mice, and the like.

In some implementations, the computing device 700 includes a display 725. In some implementations, the display 725 includes an external display connected via a video or display port. In some implementations, the display 725 is housed within a housing of the computing device 700. For example, the display 725 includes a screen of a tablet, laptop, smartphone, or other mobile device. In implementations where the display 725 includes a touch screen, the display 725 also serves as an input device 720.

The component 605 is coupled to a substrate 610. The substrate 610 is a portion of material that mechanically supports the component 605. In some implementations, the substrate 610 also electrically couples various components mounted to the substrate 610 via conductive traces, tracks, pads, and the like. For example, the substrate 610 electrically couples the die 200 to one or more other components via a solder bump 135, as further described above in conjunction with FIG. 1. The solder bump 135 is coupled to an external conductive pad 415A of the die 200 to couple the component 605 to the substrate 610. While FIG. 7 shows a solder bump 135 coupled to the external conductive pad 415A, other connectors are used to couple the component 605 to the substrate 610 in other implementations. In some implementations, the component 605 is coupled to the substrate 610 via a socket (not shown), where the component 605 is soldered to or otherwise mounted in the socket. In other implementations, as shown in FIG. 6, the component 605 is directly coupled to the substrate 610 via a direct solder connection or other connection. In some implementations, the component 605 is coupled to the substrate 610 using a land grid array (LGA), pin grid array (PGA), or other packaging technology as can be appreciated. In some implementations, the substrate 610 includes a printed circuit board (PCB), while in other implementations the substrate 610 is another semiconductor device, like die 200 (which may include active components therein). I

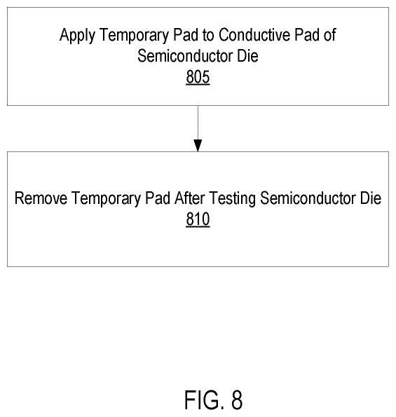

For further explanation, FIG. 8 sets forth a flowchart illustrating an example method for testing a semiconductor die 200. The method shown in FIG. 8 includes applying 805 a temporary pad 225 to a conductive pad 220A, 220B of the semiconductor die 200. In various implementations, the temporary pad 225 is applied to a top surface of the conductive pad 220A, 220B, with the top surface of the conductive pad 220A, 220B a surface that is parallel to an active pad 205A, 205B included in the die 200. In some implementations, the temporary pad 225 is applied 805 as a layer of solder to the top surface of the conductive pad 220A, 220B. As another example, the temporary pad 225 is a layer of metal applied 805 through electroplating to the conductive pad 220A, 220B. Examples of metals applied 805 as the temporary pad 225 include aluminum or copper, while other conductive materials are applied 805 to the conductive pad 220A, 220B in other implementations.

With the temporary pad 225 applied to the conductive pad 220A, 220B, the semiconductor die 200 is tested by contacting a probe to the temporary pad 225. Hence, the temporary pad 225 prevents the probe from contacting the conductive pad 220A, 220B during testing. This protects the conductive pad 220A, 220B from being damaged by the probe (e.g., prevents the probe from scratching or creating voids in the conductive pad 220A, 220B during testing). In some implementations, testing the semiconductor die 200 is known good die (KGD) testing, so the probe transmits logic patterns to the semiconductor die 200 through the temporary pad 225, the conductive pad 220A, 220B, and a via 215 coupling the conductive pad 220A, 220B to an active pad 205A, 205B of the semiconductor die 200. Thus, the temporary pad 225 allows the semiconductor die 200 to be tested, while protecting a conductive pad 220A, 220B from being damaged during testing.

After the semiconductor die 200 has been tested, the temporary pad 225 is removed 810 from the conductive pad 220A, 220B. For example, the temporary pad 225 is removed 810 after one or more tests have been executed using the probe. Removing 810 the temporary pad 225 reveals a surface of the conductive pad 220A, 220B to which the temporary pad 225 was applied 805. For example, removing the temporary pad 225 reveals a top surface of the conductive pad 220A, 220B. As a probe contacts the temporary pad 225 during testing, the revealed surface of the conductive pad 220A, 220B is undamaged from testing, allowing the revealed surface of the conductive pad 220A, 220B to be used for coupling the semiconductor die 200 to another device. In some implementations, the temporary pad 225 is removed 810 through grinding, while in other implementation the temporary pad 225 is removed 810 using chemical mechanical polishing. However, the temporary pad 225 is removed 810 using other methods in other implementations.

As the temporary pad 225 protects the conductive pad 220A, 220B from the probe, after testing, the conductive pad 220A, 220B remains suitable for use to connect one or more devices to the semiconductor die 200. In various implementations, the conductive pad 220A, 220B is coupled to an active pad 205A, 205B of the semiconductor die 200 using a via 215 passing through a passivation layer 210 on top of the active pad 205A, 205B. After the temporary pad 225 is removed 810, a second passivation layer 405 is applied on top of the conductive pad 220A, 220B, and a via 410 through the second passivation layer 405 couples the conductive pad 220A, 220B to an external conductive pad 415A, 415B, as further described above in conjunction with FIG. 4. In some implementations, a bond layer 400 covers the conductive pad 220A, 220B and the second passivation layer 405 is applied on top of the bond layer 400. The second via 410 traverses through the bod layer 400 and the second passivation layer 405 in such implementations. The external conductive pad 415A, 415B is used to couple the semiconductor die 200 to another component. For example, a solder bump is applied to the external conductive pad 415A, 415B for coupling the external conductive pad 415A, 415B to another device. In some implementations, portions of the conductive pad 220A, 220B are removed after the temporary pad 225 is removed, with a remaining portion 510A, 510B of the conductive pad 220A, 220B coupled to the via 410 that traverses through the second passivation layer 405 to the external conductive pad 415A, 415B, as further described above in conjunction with FIG. 5.

In view of the explanations set forth above, readers will recognize that application of a temporary pad to a conductive pad of a semiconductor die allows the die to be tested without damaging the conductive pad used for testing. For example, the temporary pad is a layer of solder or a layer of metal applied to a surface of the conductive pad, and a probe used for testing contacts the temporary pad rather than a surface of the conductive pad. This allows the temporary pad to protect the surface of the conductive pad from damage by having a probe used for testing contact the temporary pad rather than contact the conductive pad itself. Preventing the probe from contacting the conductive pad allows the conductive pad to be subsequently used in a connection between the semiconductor die and another device. This increases a number of conductive pads that are able to used for bonding the semiconductor die to another device, allowing more efficient usage of the area of the semiconductor die.

It will be understood from the foregoing description that modifications and changes can be made in various implementations of the present disclosure. The descriptions in this specification are for purposes of illustration only and are not to be construed in a limiting sense. The scope of the present disclosure is limited only by the language of the following claims.

What is claimed is:

1. A method comprising:
applying a temporary pad to a conductive pad of a semiconductor die; and
after testing the semiconductor die, removing the temporary pad.

2. The method of claim 1, wherein testing the semiconductor die comprises:
coupling a probe to the temporary pad; and
executing one or more tests of the semiconductor die using the probe.

3. The method of claim 2, wherein removing the temporary pad comprises:
removing the temporary pad from the conductive pad after executing the one or more tests.

4. The method of claim 1, wherein removing the temporary pad comprises:
grinding away the temporary pad to expose the conductive pad.

5. The method of claim 1, wherein removing the temporary pad comprises:
chemical-mechanical polishing away the temporary pad to expose the conductive pad.

6. The method of claim 1, wherein the conductive pad is coupled to an active pad of the semiconductor die by a via passing through a passivation layer covering the active pad.

7. The method of claim 6, further comprising:
applying a bonding layer to a top surface of the passivation layer after removing the temporary pad, the bonding layer covering the conductive pad.

8. The method of claim 7, further comprising:
applying a second passivation layer to a top surface of the bonding layer; and
forming a second via in the second passivation layer, the second via traversing through the second passivation layer and having an end coupled to the conductive pad and an opposite end coupled to an external conductive pad.

9. The method of claim 8, further comprising:
applying a solder bump to the external conductive pad.

10. The method of claim 6, further comprising:
removing one or more portions of the conductive pad to leave a remaining portion of the conductive pad;
applying a second passivation layer to a top surface of the conductive pad; and
forming a second via in the second passivation layer, the second via traversing through the second passivation layer and having an end coupled to the remaining portion of the conductive pad and an opposite end coupled to an external conductive pad.

11. The method of claim 1, wherein applying the temporary pad on the conductive pad comprises:
applying a layer of metal to a top surface of the conductive pad.

12. The method of claim 11, wherein applying the layer of metal to the top surface of the conductive pad comprises:
electroplating the layer of metal to the top surface of the conductive pad.

13. The method of claim 1, wherein applying the temporary pad on the conductive pad comprises:
applying a layer of solder to a top surface of the conductive pad.

14. A semiconductor die comprising:
an active pad covered by a passivation layer;
a via traversing through the passivation layer, an end of the via coupled to the active pad and an opposite end of the via coupled a conductive pad; and
a temporary pad applied to the conductive pad.

15. The semiconductor die of claim 14, wherein the temporary pad is applied to a top surface of the conductive pad.

16. The semiconductor die of claim 14, wherein the temporary pad comprises a layer of metal.

17. The semiconductor die of claim 14, wherein the layer of metal is electroplated to the temporary pad.

18. The semiconductor die of claim 14, wherein the temporary pad comprises a layer of solder.

19. A semiconductor die comprising:
an active pad;
a passivation layer covering the active pad;
a via traversing through the passivation layer, an end of the via coupled to the active pad;
a second passivation layer applied to a surface of the passivation layer nearest an opposite end of the via from the end of the via; and
a second via traversing through the second passivation layer and having a first end coupled to the opposite end of the via and a second end coupled to an external conductive pad.

20. The semiconductor die of claim 19, wherein the opposite end of the via is coupled to a conductive pad positioned on top of the passivation layer and the second end of the second via is coupled to the conductive pad.
